(19) United States
(12) Patent Application Publication
(10) Pub. No.: US 2017/0358635 A1
(43) Pub. Date: Dec. 14, 2017

(54) DISPLAY DEVICE

(71) Applicant: KONICA MINOLTA, INC., Tokyo (JP)

(72) Inventors: Kazuyoshi OMATA, Akishima-shi, Tokyo (JP); Tsukasa YAGI, Kobe-shi, Hyogo (JP)

(73) Assignee: KONICA MINOLTA, INC., Tokyo (JP)

(21) Appl. No.: 15/518,415

(22) PCT Filed: Oct. 5, 2015
(86) PCT No.: PCT/JP2015/078186

§ 371 Date: Apr. 11, 2017

(30) Foreign Application Priority Data
Oct. 21, 2014 (JP) 2014-214828

(51) Int. Cl. H01L 27/32; H01L 51/50; G02F 1/1335

(52) U.S. Cl. CPC H01L 27/3232; G02F 1/133621; H01L 51/504; H01L 27/322; G02F 1/133514; G02F 1/133603; G02F 2001/133612; G02F 2001/133622; G02F 2201/44

(57) ABSTRACT

To provide a display device capable of lowering power consumption while reducing a weight by using the organic electroluminescence element for the backlight.

A display device that is provided with a light-transmitting shutter element panel wherein shutter elements that control light transmission are arranged in a matrix and with a backlight panel that has organic electroluminescence elements and that is arranged so as to overlap the shutter element panel. The area in which the shutter elements are arrayed on the shutter element panel is partitioned into partitioned areas, and the organic electroluminescence elements are arranged so as to individually overlap the partitioned area that corresponds thereto.

### TECHNICAL FIELD

The present invention relates to a display device and particularly to a display device having a backlight panel using an organic electroluminescence element.

### BACKGROUND ART

As a backlight of a liquid crystal display device, those configured using an organic electroluminescence element are known. The organic electroluminescence element is a light-weighted and thin light-emitting element. Thus, a directly under type backlight using the organic electroluminescence element contributes to thinning and weight reduction of the entire display device.

As such a display device, cited literature 1 below, for example, describes that “a field-sequential liquid crystal display device includes a transmission-type liquid crystal panel and a backlight arranged on its rear surface side.” Moreover, it describes that “the backlight is constituted by a light emitting device including organic EL elements in which three light-emitting units whose light emission colors are red, green, and blue are layered on a substrate.”

### CITATION LIST

### Patent Literature

PTL 1: Japanese Patent Laid-Open No. 2007-172944

### SUMMARY OF INVENTION

### Technical Problem

However, the organic electroluminescence element used for the backlight of the display device described in cited literature 1 is configured by layering light emitting units of three colors. Thus, light taking-out efficiency from the light-emitting unit arranged on a lower layer is not sufficient, and an increase of power consumption is concerned in order to obtain sufficient light-emitting efficiency for light emission of each color.

Thus, an object of the present invention is to provide a display device capable of lowering power consumption while reducing a weight s by using the organic electroluminescence element for the backlight.

### Solution to Problem

The display device for achieving the object as above includes a light-transmitting shutter element panel in which shutter elements that control light transmission are arranged in a matrix; and a backlight panel that has organic electroluminescence elements and that is arranged so as to overlap the shutter element panel, wherein the area in which the shutter elements are arrayed on the shutter element panel is partitioned into partitioned areas, and the organic electroluminescence elements are arranged so as to individually overlap the partitioned area that corresponds thereto.

### Advantageous Effects of Invention

According to the display device configured as above, it is possible to lower power consumption while reducing a weight by using the organic electroluminescence element for the backlight.

### BRIEF DESCRIPTION OF DRAWINGS

FIG. 1 is a schematic plan view of an essential part for explaining planar configuration of a display device of a first embodiment.

FIG. 2 is a schematic sectional view of an essential part for explaining layered configuration of the display device of the first embodiment.

FIG. 3 is a schematic sectional view of an organic electroluminescence element provided in the display device of the first embodiment.

FIG. 4 is a timing chart for explaining a driving method of the display device of the first embodiment.

FIG. 5 is a schematic plan view of an essential part for explaining planar configuration of a display device of a second embodiment.

FIG. 6 is a schematic sectional view of an essential part for explaining layer configuration of the display device of the second embodiment.

FIG. 7 is a schematic sectional view of an organic electroluminescence element provided in the display device of the second embodiment.

FIG. 8 is a timing chart for explaining a driving method of the display device of the second embodiment.

### DESCRIPTION OF EMBODIMENTS

### First embodiment

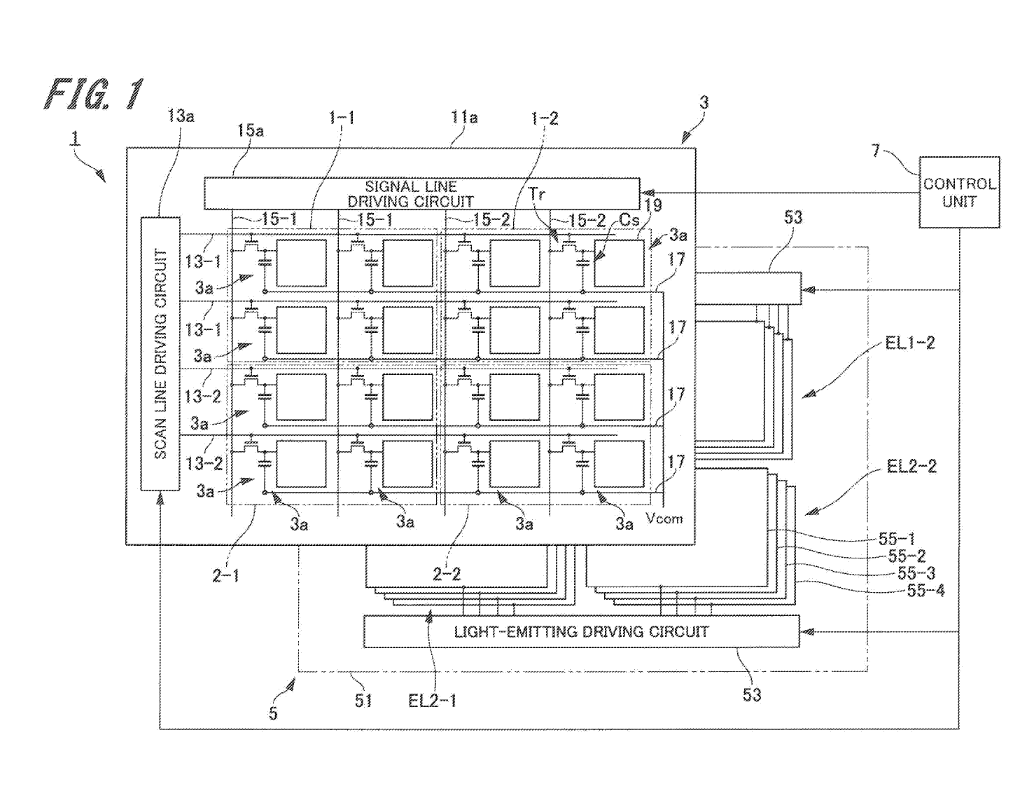

FIGS. 1 to 3 are views for explaining configuration of a display device 1 of a first embodiment to which the present invention is applied. The display device 1 illustrated in these figures is the one that the present invention is applied to a so-called field-sequential system device and has configuration in which a transmission-type shutter element panel 3 and a backlight panel 5 using organic electroluminescence elements are layered. Hereinafter, the configuration of the display device 1 will be described in order of planar configuration of the shutter element panel 3, layer configuration of the shutter element panel 3, planar configuration of the backlight panel 5, layer configuration of the backlight panel 5, and a driving method of the display device 1.

### <Planar Configuration of Shutter Element Panel 3>

FIG. 1 is a schematic plan view of an essential part for explaining the planar configuration of the display device 1 of the first embodiment. The shutter element panel 3 in the display device 1 illustrated in the view is a liquid crystal display panel, for example, in which a liquid crystal layer is sandwiched between two substrates. Note that, in FIG. 1, a plan view of one of the substrates (first substrate 11a) is illustrated as the shutter element panel 3.

A plurality of shutter elements 3a is arranged in a matrix on the first substrate 11a of the shutter element panel 3. An area where the shutter elements 3a are arranged is a display area in the display device 1 and is partitioned into a plurality of areas in a one-dimensional direction or in a two-dimensional direction. Here, as an example, it is assumed that the display area is partitioned into four areas in the two-dimensional direction. The respective partitioned areas are a first partitioned area 1-1, a second partitioned area 1-2 located in its row direction (right direction on the figure), a third partitioned area 2-1 and a fourth partitioned area 2-2 located on their column direction (lower direction on the figure) from upper left on the figure.

Further, on the first substrate 11a, a plurality of first scan lines 13-1 and second scan lines 13-2 is wired in a row direction (horizontal direction, here), a plurality of first signal lines 15-1 and second signal lines 15-2 is wired in the column direction (perpendicular direction, here), and one shutter element 3a is provided at each of intersection portions thereof.

Among them, the first scan lines 13-1 are wired corresponding to the first partitioned area 1-1 and the second partitioned area 1-2 arrayed in the row direction. Moreover, the second scan lines 13-2 are wired to the third partitioned area 2-1 and the fourth partitioned area 2-2 arrayed in the row direction. On the other hand, the first signal lines 15-1 are wired corresponding to the first partitioned area 1-1 and the third partitioned area 2-1 arrayed in the column direction. Moreover, the second signal lines 15-2 are wired corresponding to the second partitioned area 1-2 and the fourth partitioned area 2-2 arrayed in the column direction.

Moreover, on the first substrate 11a, common wirings 17 are wired in parallel with the first scan line 13-1 and the second scan line 13-2. Moreover, in a peripheral edge portion on the first substrate 11a, a scan line driving circuit 13a for scan-driving the first scan line 13-1 and the second scan line 13-2 and a signal line driving circuit 15a for supplying a video signal (that is, an input signal) corresponding to brightness information to the first signal line 15-1 and the second signal line 15-2 are arranged.

The scan line driving circuit 13a and the signal line driving circuit 15a are connected to a control unit 7, and it is so configured that driving of the first scan line 13-1 and the second scan line 13-2 as well as the first signal line 15-1 and the second signal line 15-2 is controlled by an instruction from the control unit 7. Note that the control unit 7 may be provided in the display device 1 or may be provided as an external device.

In each of the shutter elements 3a, an opening/closing circuit of the shutter including a thin film transistor Tr and a holding capacitor Cs, for example, is provided, and pixel electrodes 19 are connected to these opening/closing circuits. The opening/closing circuit is a so-called pixel circuit. Note that the pixel electrode 19 is assumed to be provided on an inter-layer insulating film covering the opening/closing circuit as will be described later in detail by use of a plan view and a sectional view.

Each of the thin film transistors Tr has a gate electrode connected to the first scan line 13-1 or the second scan line 13-2, a source electrode connected to the first signal line 15-1 or the second signal line 15-2, and a drain electrode connected to the holding capacitor Cs and the pixel electrode 19. Here, a row of the thin film transistors Tr of the shutter elements 3a arranged along each of the first scan line 13-1 and the second scan line 13-2 connect the gate electrodes to one first scan line 13-1 or second scan line 13-2 in a state sharing it. Further, the other electrode of the capacitor element Cs is connected to the common wiring 17. Note that the common wiring 17 is connected to a common electrode on the second substrate side, not shown, here.

As a result, a video signal written from the first signal line 15-1 or the second signal line 15-2 through the thin film transistor Tr is held in the holding capacitor Cs, and it is configured such that a voltage according to a held signal amount is supplied to each of the pixel electrodes 19.

The configuration of the opening/closing circuit as above is only an example, and a capacitor element may be provided in the opening/closing circuit as necessary or the opening/closing circuit may be configured by provision of a plurality of the transistors. Further, in a peripheral area of the first substrate 11a, a necessary driving circuit may be further added in accordance with a change of the opening/closing circuit.

Note that, in the views, the configuration in which the first partitioned area 1-1 to the fourth partitioned area 2-2 are arranged on the first substrate 11a, and the shutter elements 3a in two rows and two columns are arranged on each of these first partitioned area 1-1 to fourth partitioned area 2-2 is illustrated, but in an actual display device, necessary numbers of the partitioned areas and the shutter elements 3a are arranged both in the row direction and in the column direction. The shutter element panel 3 having such partitioned areas may be configured such that a plurality of panels in which the shutter elements 3a are arrayed on the individual substrates is bonded together or a plurality of liquid crystal display panels fabricated for each partitioned area, for example, is bonded together. In that case, a diffusion film for making a joint inconspicuous may be provided on a bonded portion between the panels. Moreover, the shutter element panel 3 is not limited to the liquid crystal display panel but may be an element panel whose optical aperture can be freely opened/closed for each pixel. Such a shutter element panel may be a MEMS shutter element panel in which a micro machine (Micro Electro Mechanical Systems: MEMS) shutter is incorporated for each pixel, for example.

### <Layer Configuration of Shutter Element Panel 3>

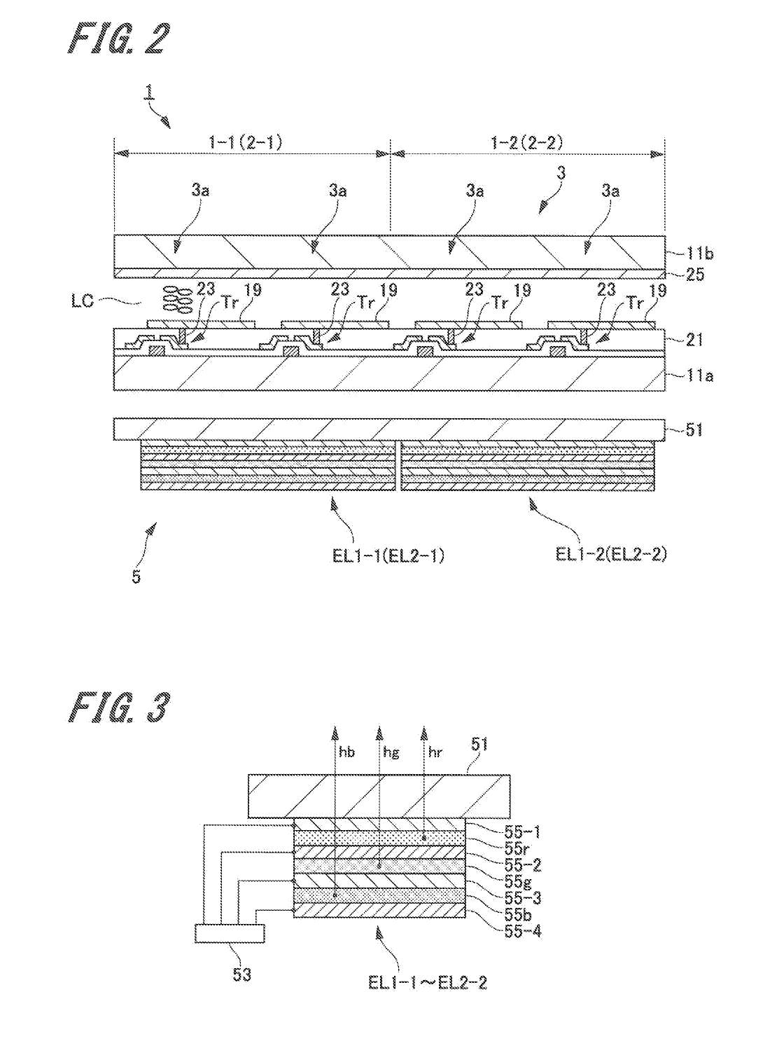

FIG. 2 is a schematic sectional view of an essential part for explaining the layer configuration of the display device 1 of the first embodiment and is a view corresponding to a row-direction section in the display area in FIG. 1. As illustrated in the view, in the shutter element panel 3, a liquid crystal layer LC is sandwiched between the first substrate 11a and a second substrate 11b made of a transparent material such as a glass substrate or a plastic substrate. The circuit described by use of FIG. 1 is formed on the first substrate 11a among them.

The thin film transistor Tr and the capacitor element, the scan line, the signal line, and the common wiring (for them, see FIG. 1), not shown, here, are provided on a plane facing the liquid crystal layer LC side of the first substrate 11a. They are covered by an inter-layer insulating film 21. The pixel electrodes 19 are arrayed/formed on a top part of the inter-layer insulating film 21. Each of the pixel electrodes 19 is constituted by a conductive material having light permeability and is connected to the drain electrode of the thin film transistor Tr through a connection hole 23 provided in the inter-layer insulating film 21.

A surface side on which the pixel electrode 19 is formed in the first substrate 11a on a driving side as above is covered by an oriented film, not shown, here, and the liquid crystal layer LC is provided through the oriented film.

On the other hand, a common electrode 25 is provided on a surface facing the liquid crystal layer LC side of the second substrate 11b arranged opposite to the first substrate 11a through the liquid crystal layer LC. The common electrode 25 is constituted by a conductive material having light permeability and is provided in a solid film state having a potential common with all the shutter elements 3a. Further, the surface side on which the common electrode 25 is formed in the second substrate 11b is covered by the oriented film, not shown, here, and the liquid crystal layer LC is provided through the oriented film.

The liquid crystal layer LC provided between the oriented film on the first substrate 11a and the oriented film of the second substrate 11b as above includes a liquid crystal molecule driven by on/off of the pixel electrode 19. A layer thickness of the liquid crystal layer LC is assumed to be held to a predetermined layer thickness (cell gap) by provision of a spacer (not shown) sandwiched between the first substrate 11a and the second substrate 11b.

Then, a pair of deflecting plates, not shown, here, are arranged on outer sides of the first substrate 11a and the second substrate 11b above, and the backlight panel 5 is arranged on the outer side of the deflecting plate on the first substrate 11a side so as to constitute the display device 1.

### <Planar Configuration of Backlight Panel 5>

As illustrated in FIG. 1, the backlight panel 5 includes organic electroluminescence elements EL1-1 to EL2-2 and are arranged on the first substrate 11a side in the shutter element panel 3. The backlight panel 5 includes organic electroluminescence elements EL1-1 to EL2-2 on one major surface of a transparent substrate 51. Here, it is configured, as an example, such that the organic electroluminescence elements EL1-1 to EL2-2 are arranged on a surface on a side opposite to the shutter element panel 3 in the transparent substrate 51.

The organic electroluminescence elements EL1-1 to EL2-2 are arranged individually and corresponding to the first partitioned area 1-1 to the fourth partitioned area 2-2 so as to overlap the first partitioned area 1-1 to the fourth partitioned area 2-2 in the shutter element panel 3. That is, the organic electroluminescence element EL1-1 is arranged so as to overlap the first partitioned area 1-1, the organic electroluminescence element EL1-2 is arranged so as to overlap the second partitioned area 1-2, the organic electroluminescence element EL2-1 is arranged so as to overlap the third partitioned area 2-1, and the organic electroluminescence element EL2-2 is arranged so as to overlap the fourth partitioned area 2-2. Note that, for explanation, a state where the shutter element panel 3 and the backlight panel 5 are shifted is illustrated in FIG. 1, but the organic electroluminescence elements EL1-1 to EL2-2 are layered one-to-one on the first partitioned area 1-1 to the fourth partitioned area 2-2.

Further, a light-emitting driving circuit 53 for driving the organic electroluminescence elements EL1-1 to EL2-2 is connected to the transparent substrate 51. The light-emitting driving circuit 53 individually supplies a voltage for controlling light emission of each of the light emitting units to a first electrode 55-1 to a fourth electrode 55-4 of the organic electroluminescence elements EL1-1 to EL2-2 which will be described later in detail.

Moreover, it is so configured that the light-emitting driving circuit 53 is connected to the control unit 7, and an applied voltage to the first electrode 55-1 to the fourth electrode 55-4 of the organic electroluminescence elements EL1-1 to EL2-2 is controlled by an instruction from the control unit 7.

Note that, although not shown, here, the diffusion film may be arranged between each of the organic electroluminescence elements EL1-1 to EL2-2. As a result, a joint between the elements which are non-light emitting portions is made inconspicuous, and in-plane uniformity of brightness in the backlight panel 5 is maintained.

Moreover, the backlight panel 5 having the organic electroluminescence elements EL1-1 to EL2-2 as above may be such that a plurality of panels in which the organic electroluminescence elements are provided on the individual substrates is bonded. In this case, the diffusion film for making the joint inconspicuous may be provided on a bonded portion between the panels.

### <Layer Configuration of Backlight Panel 5>

As illustrated in FIGS. 1 and 2, the backlight panel 5 has configuration in which the organic electroluminescence elements EL1-1 to EL2-2 are arranged on a surface on a side opposite to the shutter element panel 3 in the transparent substrate 51 such as a glass substrate or a plastic substrate. Emission light obtained by the organic electroluminescence elements EL1-1 to EL2-2 is taken out to the shutter element panel 3 side through the transparent substrate 51. Configuration of the organic electroluminescence elements EL1-1 to EL2-2 is as follows.

FIG. 3 is a schematic sectional configuration view of the organic electroluminescence elements EL1-1 to EL2-2. As illustrated in the view, the organic electroluminescence elements EL1-1 to EL2-2 are layered elements and each have a first electrode 55-1, a second electrode 55-2, a third electrode 55-3, and a fourth electrode 55-4, for example, in order from the transparent substrate 51 side. Light-emitting units of different light emission colors are sandwiched between these electrodes.

As an example, a red light-emitting unit 55r is sandwiched between the first electrode 55-1 and the second electrode 55-2. Either one of the first electrode 55-1 and the second electrode 55-2 functions as an anode with respect to the red light-emitting unit 55r, while the other functions as a cathode. The red light-emitting unit 55r is configured to obtain emission light hr of red (R) by recombination between a positive hole injected from the anode and an electron injected from the cathode.

Moreover, a green light-emitting unit 55g is sandwiched between the second electrode 55-2 and the third electrode 55-3. Either one of the second electrode 55-2 and the third electrode 55-3 functions as an anode with respect to the green light-emitting unit 55g, while the other functions as a cathode. The green light-emitting unit 55g is configured to obtain emission light hg of green (G) by recombination between a positive hole injected from the anode and an electron injected from the cathode.

Furthermore, a blue light-emitting unit 55b is sandwiched between the third electrode 55-3 and the fourth electrode 55-4. Either one of the third electrode 55-3 and the fourth electrode 55-4 functions as an anode with respect to the blue light-emitting unit 55b, while the other functions as a cathode. The blue light-emitting unit 55b is configured to obtain emission light hb of blue (B) by recombination between a positive hole injected from the anode and an electron injected from the cathode.

In the first electrode 55-1 to the fourth electrode 55-4 as above, the first electrode 55-1, the second electrode 55-2, and the third electrode 55-3 which the emission lights hr, hg, and hb obtained in the light-emitting units 55r, 55g, and 55b transmit are constituted by use of a conductive material having light permeability. As the conductive material having such light permeability, oxide semiconductors such as ITO (indium-tin oxide), ZnO (zinc oxide), TiO₂ (titanium oxide), SnO₂ (tin oxide), IZO (registered trademark: indium zinc oxide) and moreover, silver (Ag) in a thin-film state to such a degree that has light permeability are used.

Particularly, these first electrode 55-1, the second electrode 55-2, and the third electrode 55-3 are preferably constituted by a silver thin film which has low resistance but sufficient light permeability. When the silver thin film is used, a layer which can ensure film-forming uniformity of the silver thin film such as a nitrogen-containing layer is preferably provided as its film-forming base layer. Such a layer preferably functions both as a positive hole-injecting layer and as an electron injecting layer, for example, as a part of the light-emitting unit. Note that the silver thin film is preferably used as an anode.

On the other hand, the fourth electrode 55-4 is constituted by use of a conductive material having light reflectivity. As the conductive material having such light reflectivity, a metal material such as aluminum is used, and a material considering a work function is selected from these materials and used.

Entire layer configuration of the red light-emitting unit 55r, the green light-emitting unit 55g, and the blue light-emitting unit 55b is not limited as a light-emitting unit of the organic electroluminescence element. Configuration in which [positive hole-injecting layer/positive hole transport layer/light-emitting layer/electron transport layer/electron injecting layer] are layered in order from the anode side is exemplified as an example. It is indispensable to have the light-emitting layer constituted by use of at least an organic material in them. The positive hole-injecting layer and the positive hole transport layer may be provided as a positive hole transport/injecting layer. The electron transport layer and the electron injecting layer may be provided as an electron transport/injecting layer.

Moreover, in the red light-emitting unit 55r, the green light-emitting unit 55g, and the blue light-emitting unit 55b, a layering order from the transparent substrate 51 side is not limited, and it is only necessary that they are arranged in the layering order suitable for the respective characteristics. Moreover, the light-emitting units of different colors constituting each of the organic electroluminescence elements EL1-1 to EL2-2 are not limited to the red light-emitting unit 55r, the green light-emitting unit 55g, and the blue light-emitting unit 55b, but those which can obtain emission lights of complementary colors of them or the one which can obtain white emission light may be further layered. As described above, it is possible to reduce light emission from the light-emitting unit with low light emission efficiency by further layering the light-emitting units which can obtain emission light of the complementary color or the white emission light, and thus, lower power consumption can be expected. Moreover, the light-emitting units of different colors constituting each of the organic electroluminescence elements EL1-1 to EL2-2 may have configuration of layering the light-emitting units emitting lights of respective complementary colors of RGB.

The organic electroluminescence elements EL1-1 to EL2-2 as above can freely emit the emission light hr of red (R), emission light hg of green (G), and emission light hb of blue (B) by applying an arbitrary voltage to the first electrode 55-1 to the fourth electrode 55-4 from the light-emitting driving circuit 53 in accordance with an instruction from the control unit 7.

Moreover, in the above, at least any one of the first electrode 55-1 to the fourth electrode 55-4 constituting each of the organic electroluminescence elements EL1-1 to EL2-2 may be provided as a common electrode in common to all the organic electroluminescence elements EL1-1 to EL2-2. Typically, either one of the electrodes on an outermost surface, that is, the first electrode 55-1 or the fourth electrode 55-4 is provided as a common electrode in common to all the organic electroluminescence elements EL1-1 to EL2-2. Further, other than that, depending on the configuration and the driving method of the organic electroluminescence elements EL1-1 to EL2-2, both the first electrode 55-1 and the fourth electrode 55-4 may be made common electrodes or the second electrode 55-2 or the third electrode 55-3 arranged in the middle may be made a common electrode.

Moreover, in each layer constituting the organic electroluminescence elements EL1-1 to EL2-2 as above, a forming method thereof is not limited but an appropriate method such as a vapor deposition method or an application method is employed. Moreover, each light-emitting unit of the organic electroluminescence elements EL1-1 to EL2-2 has a light-emitting layer constituted by use of at least an organic material. Thus, it is assumed that the layer is sealed by a sealing member, not shown, here, but its sealing structure is not limited but the layer may have a hollow structure or a sealant-filled structure.

### <Driving Method of Display Device 1>

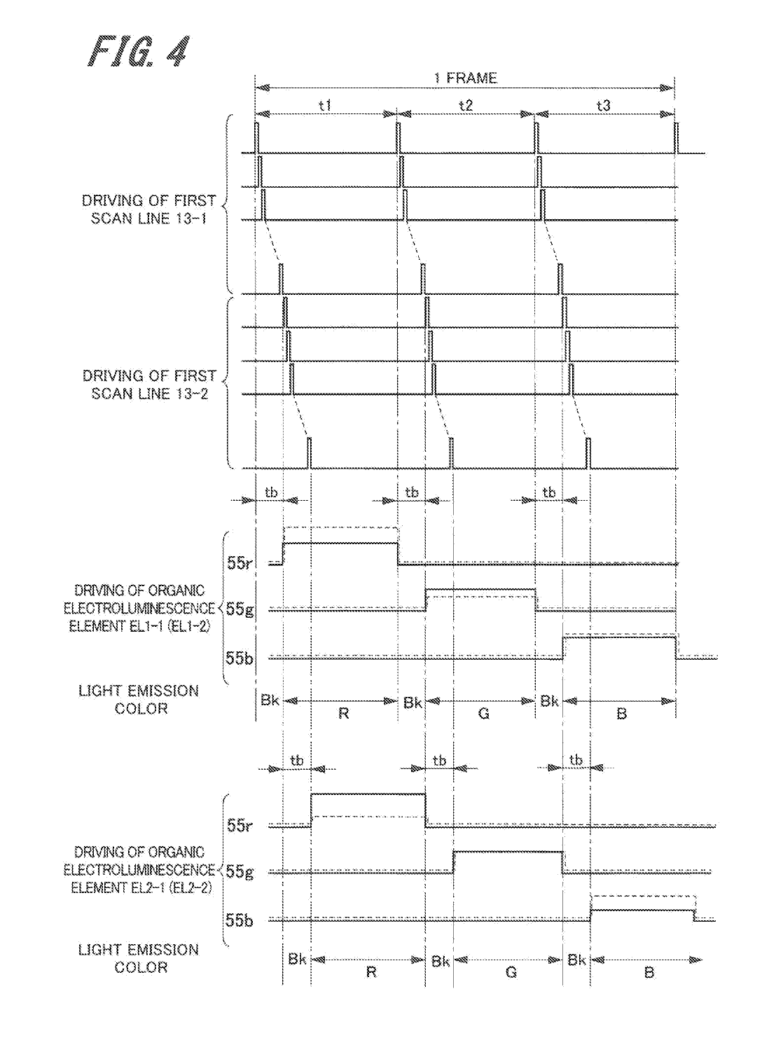

FIG. 4 is a timing chart for explaining a driving method of the display device 1 and illustrates a period of frame. The driving method of the display device 1 performed by the control unit 7 will be described below with reference to FIGS. 1 to 3 above together with FIG. 4.

Note that, in the timing chart for driving of the first scan line 13-1 and the second scan line 13-2 in FIG. 4, a high-period is an on-state of a gate of the thin film transistor Tr. Moreover, in the timing chart for driving of the organic electroluminescence elements EL1-1 to EL2-2, a high-period indicates a light emission period of each light-emitting unit.

First, the scan line driving circuit 13a in the shutter element panel 3 sequentially supplies a row selection signal to the first scan line 13-1 to the second scan line 13-2 at each of a first period t1 to a third period t3 obtained by dividing 1 frame. At this time, after the row selection signal has been supplied to a first row to a last row of the first scan line 13-1, the row selection signal is supplied to a first row to a last row of the second scan line 13-2 continuously to that. As a result, in each of the first period t1 to the third period t3, all the shutter elements 3a are sequentially selected for each row.

Here, the number of divisions of 1 frame is assumed to correspond to the number of light emission colors of the light-emitting unit provided in the backlight panel 5 (3 colors of R, G, and B, here). The divided first period t1 to the third period t3 are periods assigned to the light emission colors of the light-emitting units provided in the backlight panel 5.

On the other hand, the signal line driving circuit 15a supplies a video signal corresponding to the brightness information to each of the first signal line 15-1 and the second signal line 15-2 in accordance with timing of supply of the row selection signal to the first scan line 13-1 and the second scan line 13-2.

As a result, a voltage according to the signal amount supplied from each of the first signal line 15-1 and the second signal line 15-2 is applied to the pixel electrode 19 of each of the shutter elements 3a connected to the selected first scan line 13-1 to the second scan line 13-2, and the shutter of each of the shutter elements 3a is opened in accordance with the voltage. Here, a liquid crystal molecule of the liquid crystal layer LC corresponding to each of the pixel electrode 19 portions is tilted in accordance with the voltage applied to the pixel electrode 19, whereby the shutter element 3a is opened at an aperture ratio according to the signal amount supplied from each of the first signal line 15-1 and the second signal line 15-2.

Then, when selection of all the first scan line 13-1 to the second scan line 13-2 by the scan line driving circuit 13a is finished in one period (the first period t1, for example), all the shutter elements 3a are in an open state according to the signal amount supplied from each of the first signal lines 15-1 and the second signal lines 15-2.

On the other hand, the backlight panel 5 is driven as follows within a period of 1 frame. That is, the light-emitting driving circuit 53 sequentially causes each of the light-emitting units of the organic electroluminescence elements EL1-1 to EL2-2 to emit light in the first period t1 to the third period t3 obtained by dividing 1 frame in order of the light emission colors assigned to the first period t1 to the third period t3.

If the light emission of red (R) is assigned to the first period t1, for example, each of the red light-emitting units 55r of the organic electroluminescence elements EL1-1 to EL2-2 is made to emit light in the first period t1. Similarly, the green light-emitting unit 55g is made to emit light in the second period t2, and the blue light-emitting unit 55b is made to emit light in the third period t3. At this time, the light emission in each of the light-emitting units 55r, 55g, and 55b of the organic electroluminescence elements EL1-1 to EL2-2 is handled by so-called local dimming in which brightness is adjusted, respectively, as indicated by a solid line and a broken line in FIG. 4 in accordance with the video signal corresponding to the brightness information supplied to the signal line driving circuit 15a of the shutter element panel 3. The light emission brightness of each of the organic electroluminescence elements EL1-1 to EL2-2 is brightness corresponding to the largest video signal data in that area, for example.

Each of the emission lights hr, hg, and hb generated in the first period t1 to the third period t3, respectively, transmits the shutter element 3a in accordance with the aperture ratio of the shutter element 3a in the first period t1 to the third period t3.

As a result, a feed-sequential type driving displayed in time division is performed on the emission light hr of red (R), the emission light hg of green (G), and the emission light hb of blue (B) in the period of 1 frame. In the driving, a portion corresponding to one shutter element 3a becomes 1 pixel.

Note that the light-emitting driving circuit 53 sets a period during which the first row to the last row of the first scan line 13-1 have been selected in the first period t1 to the third period t3 to a blank period tb of the organic electroluminescence elements EL1-1 and EL1-2 and stops light emission in the light-emitting units in the organic electroluminescence elements EL1-1 and EL1-2. Similarly, the light-emitting driving circuit 53 sets a period during which the first row to the last row of the second scan line 13-2 have been selected to the blank period tb of the organic electroluminescence elements EL2-1 and EL2-2 and stops light emission in the light-emitting units in the organic electroluminescence elements EL2-1 and EL2-2. As a result, in each of the blank periods tb, the area corresponding to each of the organic electroluminescence elements EL1-1 to EL2-2 becomes black display (Bk).

Moreover, the numbers of the first scan lines 13-1 and the second scan lines 13-2 are set to the same, and thereby the blank periods tb of the organic electroluminescence elements EL1-1 and EL1-2 and the blank periods tb of the organic electroluminescence elements EL2-1 and EL2-2 become the same. As a result, a transmission amount in each color is prevented from being different in each row of the shutter elements.

### Advantages of First Embodiment

The display device 1 as above has configuration in which the backlight panel 5 using an organic electroluminescence element is provided so as to overlap the shutter element panel 3 and thus, size reduction and thinning of a frame can be achieved.

In addition, the display device 1 is configured such that the organic electroluminescence elements EL1-1 to EL2-2 are provided corresponding to each of the first partitioned area 1-1 to the fourth partitioned area 2-2 obtained by partitioning the display area. As a result, light emission brightness of each of the organic electroluminescence elements EL1-1 to EL2-2 is brightness corresponding to the largest video signal data of the corresponding first partitioned area 1-1 to the fourth partitioned area 2-2, respectively. Therefore, power consumption can be reduced as compared with the case where the display area is not partitioned.

As a result, even in the time division system such as a field-sequential system, even if the display device 1 is used particularly as a display unit of a smart device whose battery capacity tends to run short, driving time of the device can be improved.

### Second Embodiment

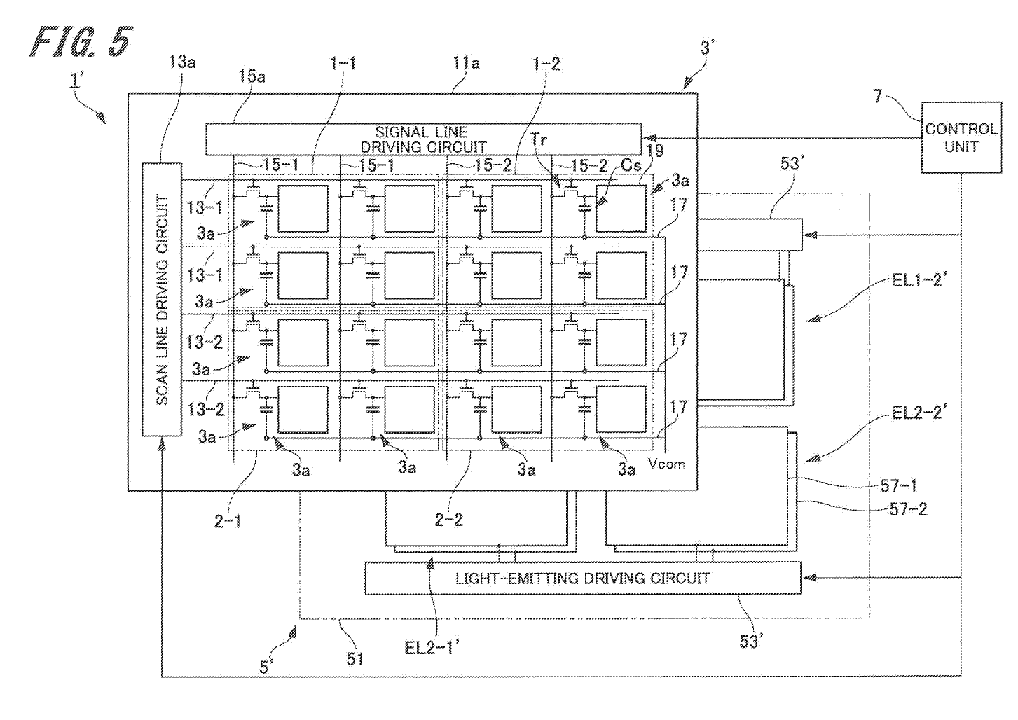

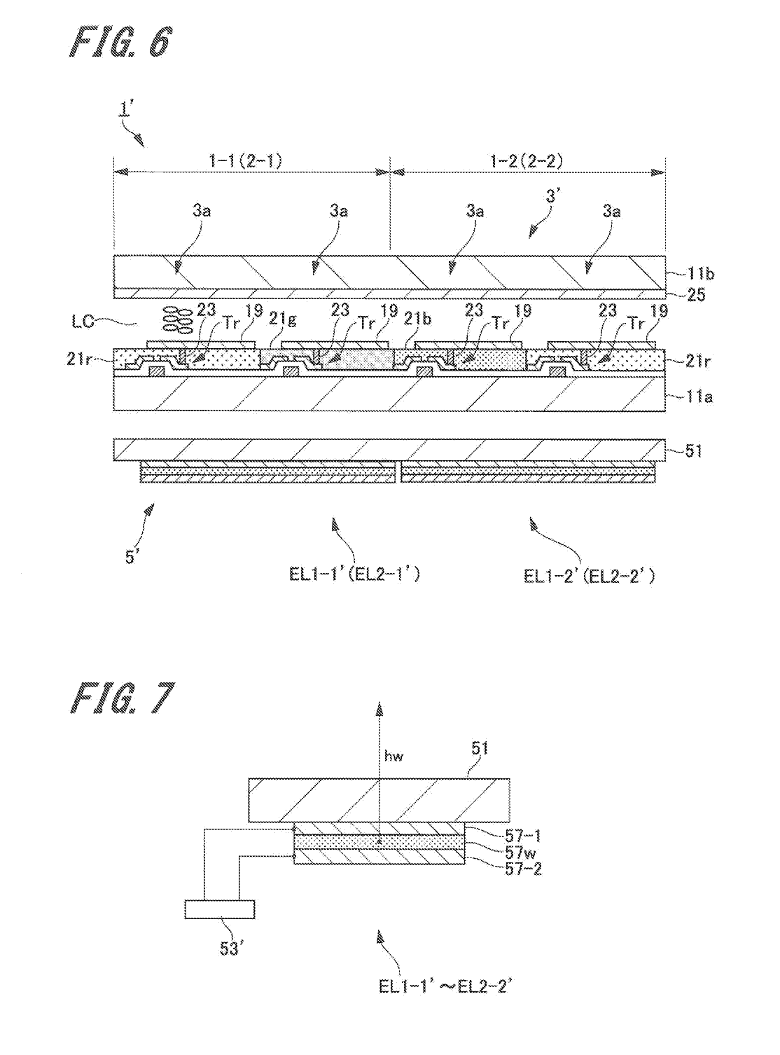

FIGS. 5 and 6 are views for explaining configuration of a display device 1′ of a second embodiment to which the present invention is applied. The display device 1′ illustrated in these views is a display device performing display in a surface division system to which the present invention is applied and differs from the display device of the first embodiment explained by use of FIGS. 1 to 4 in the layer configuration of a shutter element panel 3′, the layer configuration of a backlight panel 5′ and a driving method. The shutter element 3a and other configuration are similar to those of the first embodiment. Thus, the same reference numerals are given to constituent elements similar to those of the first embodiment below and duplicated explanation will be omitted.

### <Planar Configuration of Shutter Element Panel 3′>

FIG. 5 is a schematic plan view of an essential part for explaining planar configuration of the display device 1′ of the second embodiment. As illustrated in the view, the planar configuration of the shutter element panel 3′ is similar to the planar configuration of the shutter element panel 3′ in the first embodiment, and a display area in which the shutter element 3a is arranged is partitioned into a plurality of areas.

### <Layer Configuration of Shutter Element Panel 3′>

FIG. 6 is a schematic sectional view of an essential part for explaining layer configuration of the display device 1′ of the second embodiment and is a view corresponding to a row-direction section in the display area in FIG. 5. As illustrated in the view, the shutter element panel 3′ of the second embodiment has a color filter in each color corresponding to each of the shutter elements 3a, which is different from the display device of the first embodiment.

Here, as an inter-layer insulating film which becomes a base of the pixel electrode 19, a red filter 21r, a green filter 21g, and a blue filter 21b are pattern-formed corresponding to each of the shutter elements 3a, for example. In each of the red filter 21r, the green filter 21g, and the blue filter 21b, a connection hole 23 is provided, and the pixel electrode 19 is connected to the drain electrode of the thin film transistor Tr through the connection hole 23.

Here, a portion corresponding to one shutter element 3a constitutes a sub pixel, and three shutter element 3a portions on which the red filter 21r, the green filter 21g, and the blue filter 21b are provided constitute 1 pixel.

Note that the color filter is not limited to provision as the inter-layer insulating film but may be provided in any layer of the shutter element panel 3′ as long as it is provided corresponding to each of the shutter elements 3a. Thus, the color filter may be provided on the second substrate 11b. Alternatively, a filter transmitting white light may be provided as a color filter in addition to the red filter 21r, the green filter 21g, and the blue filter 21b so that the four shutter element 3a portions constitute 1 pixel.

### <Planar Configuration of Backlight Panel 5′>

As illustrated in FIG. 5, the backlight panel 5′ includes organic electroluminescence elements and is arranged on the first substrate 11a side in the shutter element panel 3′. The backlight panel 5′ includes organic electroluminescence elements EL1-1′ to EL2-2′ on one major surface of the transparent substrate 51, and their layer configuration is different from that of the organic electroluminescence elements of the first embodiment. The planar configuration thereof is similar to the configuration of the backlight panel of the first embodiment. That is, the organic electroluminescence elements EL1-1′ to EL2-2′ are arranged corresponding to the first partitioned area 1-1 to the fourth partitioned area 2-2 so as to overlap the first partitioned area 1-1 to the fourth partitioned area 2-2 in the shutter element panel 3′.

<Layer configuration of backlight panel 5′>

As illustrated in FIGS. 5 and 6, the backlight panel 5′ has configuration in which the organic electroluminescence elements EL1-1′ to EL2-2′ are arranged on a surface on the side opposite to the shutter element panel 3′ in the transparent substrate 51 such as a glass substrate and a plastic substrate. The emission light obtained by the organic electroluminescence elements EL1-1′ to EL2-2′ is taken out to the shutter element panel 3′ side through the transparent substrate 51. The configuration of the organic electroluminescence elements EL1-1′ to EL2-2′ is as follows.

FIG. 7 is a schematic sectional configuration view of the organic electroluminescence elements EL1-1′ to EL2-2′. As illustrated in the view, each of the organic electroluminescence elements EL1-1′ to EL2-2′ has a first electrode 57-1 and a second electrode 57-2 layered in order from the transparent substrate 51 side, for example. A white light-emitting unit 57w is sandwiched between these electrodes.

Either one of the first electrode 57-1 and the second electrode 57-2 functions as an anode with respect to the white light-emitting unit 57w, while the other functions as a cathode. The white light-emitting unit 57w is configured to obtain emission light hw of white (W) by recombination between a positive hole injected from the anode and an electron injected from the cathode.

Moreover, the first electrode 57-1 transmitting the emission light obtained in the white light-emitting unit 57w among them is constituted by use of a conductive material having light permeability. As the conductive material having such light permeability, the one similar to the first electrode 55-1 of each of the organic electroluminescence elements EL1-1 to EL2-2 of the first embodiment described above is used similarly. On the other hand, the second electrode 57-2 is constituted by use of a conductive material having light reflectivity. As the conductive material having such light reflectivity, the one similar to the fourth electrode 55-4 of each of the organic electroluminescence elements EL1-1 to EL2-2 is used similarly.

Moreover, it is only necessary that the white light-emitting unit 57w is constituted so that the emission light hw of white (W) is obtained. A color temperature of the emission light hw takes a value in a range from 2000K to 12000K. Such white light-emitting unit 57w may be constituted by layering the light-emitting units which can obtain emission lights of complementary colors to each other through an intermediate layer. Regarding the configuration of each light-emitting unit, an entire layer structure is not limited as the light-emitting unit of the organic electroluminescence element but is similar to that of the organic electroluminescence elements EL1-1 to EL2-2 of the first embodiment.

The organic electroluminescence elements EL1-1′ to EL2-2′ as above can freely emit the emission light hw of white (W) by control of the voltage to be supplied to the first electrode 57-1 and the second electrode 57-2 by a light-emitting driving circuit 53′.

Note that, in the above, either one of the first electrode 57-1 and the second electrode 57-2 may be provided as a common electrode.

Moreover, in each layer constituting the organic electroluminescence elements EL1-1′ to EL2-2′ as above, a forming method thereof is not limited but an appropriate method such as a vapor deposition method or an application method is employed. Moreover, each light-emitting unit of the organic electroluminescence elements EL1-1′ to EL2-2′ has a light-emitting layer constituted by use of at least an organic material. Thus, it is assumed that the layer is sealed by a sealing member, not shown, here, but its sealing structure is not limited but the layer may have a hollow structure or a sealant-filled structure. They are similar to the backlight panel in the display device of the first embodiment.

### <Driving Method of Display Device 1′>

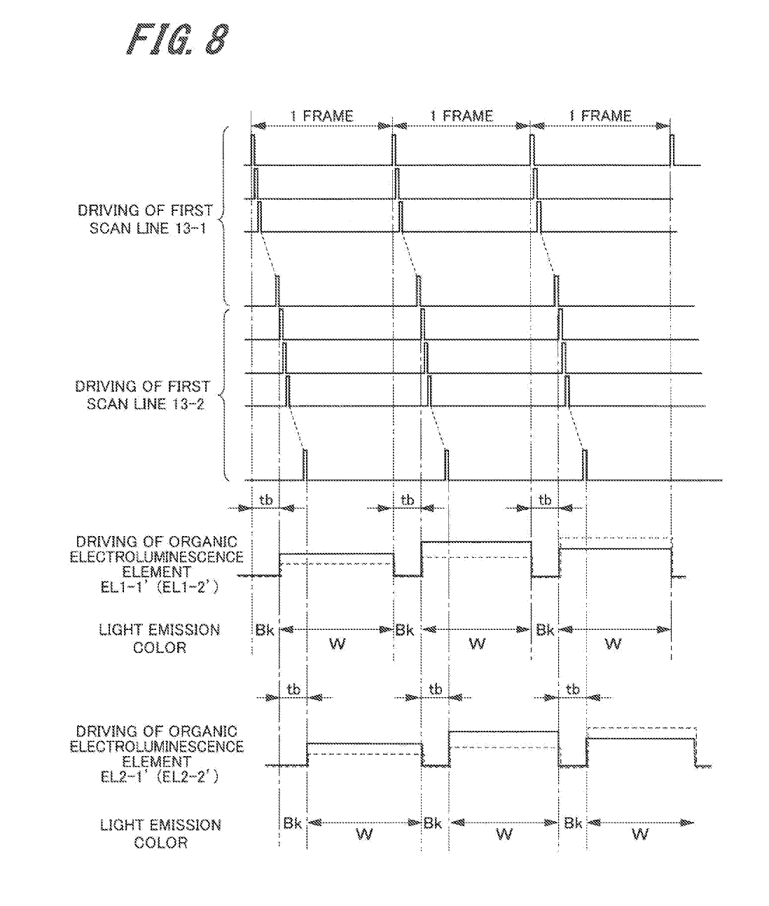

FIG. 8 is a timing chart for explaining a driving method of the display device 1′ and illustrates periods of 3 frames. The driving method of the display device 1′ will be described below with reference to FIGS. 5 to 7 above together with FIG. 8.

First, the scan line driving circuit 13a in the shutter element panel 3′ sequentially supplies a row selection signal to the first scan line 13-1 to the second scan line 13-2 at each 1 frame. At this time, after the row selection signal has been supplied to a first row to a last row of the first scan line 13-1, the row selection signal is supplied to a first row to a last row of the second scan line 13-2 continuously to that. As a result, in the period of the 1 frame, all the shutter elements 3a are sequentially selected at each row.

On the other hand, the signal line driving circuit 15a supplies a video signal corresponding to the brightness information to each of the first signal line 15-1 and the second signal line 15-2 in accordance with timing of supply of the row selection signal to the first scan line 13-1 and the second scan line 13-2.

As a result, a voltage according to the signal amount supplied from each of the first signal line 15-1 and the second signal line 15-2 is applied to the pixel electrode 19 of each of the shutter elements 3a connected to the selected first scan line 13-1 to the second scan line 13-2, and the shutter of each of the shutter elements 3a is opened in accordance with the voltage. Here, a liquid crystal molecule of the liquid crystal layer LC corresponding to each of the pixel electrode 19 portions is tilted in accordance with the voltage applied to the pixel electrode 19, whereby the shutter element 3a is opened at an aperture ratio according to the signal amount supplied from each of the first signal line 15-1 and the second signal line 15-2.

Further, in the period of 1 frame, when selection of all the first scan line 13-1 to the second scan line 13-2 by the scan line driving circuit 13a is finished, all the shutter elements 3a are opened in accordance with the signal amount supplied from each of the first signal line 15-1 and the second signal line 15-2.

On the other hand, the backlight panel 5′ causes the organic electroluminescence elements EL1-1′ to EL2-2′ to emit light within the period of 1 frame. At this time, the light emission in the organic electroluminescence elements EL1-1′ to EL2-2′ is handled by so-called local dimming in which brightness is adjusted, respectively, as indicated by a solid line and a broken line in FIG. 8 in accordance with the video signal corresponding to the brightness information supplied to the signal line driving circuit 15a of the shutter element panel 3′.

The emission light hw of white (W) generated in the period of 1 frame transmits the color filter in each color and transmits the shutter element 3a in accordance with the aperture ratio of the shutter element 3a and it is displayed in each display color.

As a result, a plane division type driving is performed in which the emission light hw of white (W) generated in each of the organic electroluminescence elements EL1-1′ to EL2-2′ in the period of 1 frame transmits the red filter 21r, the green filter 21g, and the blue filter 21b, respectively, and is displayed in each display color. In the driving, a portion corresponding to the three shutter elements 3a on which the color filters of different colors are provided constitutes 1 pixel.

Note that the light-emitting driving circuit 53′ sets a period during which the first row to the last row of the first scan line 13-1 have been selected in the 1 frame period to the blank period tb of the organic electroluminescence elements EL1-1′ and EL1-2′ and stops light emission in the light-emitting units in the organic electroluminescence elements EL1-1′ and EL1-2′. Similarly, the light-emitting driving circuit 53′ sets a period during which the first row to the last row of the second scan line 13-2 have been selected to the blank period tb of the organic electroluminescence elements EL2-1′ and EL2-2′ and stops light emission in the light-emitting units in the organic electroluminescence elements EL2-1′ and EL2-2′. As a result, in each of the blank periods tb, the area corresponding to each of the organic electroluminescence elements EL1-1′ to EL2-2′ becomes black display (Bk).

Moreover, the numbers of the first scan lines 13-1 and the second scan lines 13-2 are set to the same, and thereby the blank periods tb of the organic electroluminescence elements EL1-1′ and EL1-2′ and the blank period tb of the blank periods tb of the organic electroluminescence elements EL2-1′ and EL2-2′ become the same. As a result, a transmission amount in each color is prevented from being different in each row of the shutter elements.

### Advantages of Second Embodiment

The display device 1′ as above has configuration in which the backlight panel 5′ in which the organic electroluminescence element is provided so as to overlap the shutter element panel 3′ is provided and thus, size reduction and thinning of a frame can be achieved.

In addition, the display device 1′ is configured by provision of the organic electroluminescence elements EL1-1′ to EL2-2′ corresponding to each of the first partitioned area 1-1 to the fourth partitioned area 2-2 obtained by partitioning the display area. As a result, if a difference in display brightness is extremely large among the first partitioned area 1-1 to the fourth partitioned area 2-2, light emission brightness of the element arranged corresponding to an area with low brightness in the organic electroluminescence elements EL1-1′ to EL2-2′ can be suppressed. Therefore, power consumption can be reduced.

As a result, even in the planar division system, even if the display device 1′ is used particularly as a display unit of a smart device whose battery capacity tends to run short, driving time of the device can be improved.

### REFERENCE SIGNS LIST

1, 1′ display device

1-1 first partitioned area

1-2 second partitioned area

2-1 third partitioned area

2-1, 2-2 fourth partitioned area

3, 3′ shutter element panel

3a shutter element

5, 5′ backlight panel

13-1, 13-2 scan line

15-1, 15-2 signal line

21r red filter

21g green filter

21b blue filter

53, 53′ light-emitting driving circuit

55r red light-emitting unit

55g green light-emitting unit

55b blue light-emitting unit

57w white light-emitting unit

EL1-1 to EL2-2, EL1-1′ to EL2-2′ organic electroluminescence element

1. A display device comprising:
a light-transmitting shutter element panel in which shutter elements that control light transmission are arranged in a matrix; and
a backlight panel that has organic electroluminescence elements and that is arranged so as to overlap the shutter element panel, wherein
the area in which the shutter elements are arrayed on the shutter element panel is partitioned into partitioned areas, and the organic electroluminescence elements are arranged so as to individually overlap the partitioned area that corresponds thereto.

2. The display device according to claim 1, wherein
the area in which the shutter elements are arrayed is partitioned in two directions.

3. The display device according to claim 1, wherein
the backlight panel has a light-emitting driving circuit for individually driving the organic electroluminescence element arranged corresponding to each of the partitioned areas; and
the light-emitting driving circuit controls brightness of the organic electroluminescence element arranged corresponding to each of the partitioned areas in accordance with display brightness of each of the partitioned areas.

4. The display device according to claim 1, wherein
the organic electroluminescence element arranged in each of the partitioned areas is a layered element in which light-emitting units of different colors are sandwiched between a plurality of electrodes, respectively.

5. The display device according to claim 4, wherein
in the organic electroluminescence element, a light-emitting unit of white or of a complementary color to any of the different colors is layered in a state sandwiched between a pair of electrodes, on the light-emitting units of different colors.

6. The display device according to claim 4, wherein
the shutter element panel has a plurality of scan lines and a plurality of signal lines extended in a direction different from that of the scan lines;
each of the shutter elements is arranged in a state connected to the scan line and the signal line at each of intersection portions between the scan line and the signal line;
the backlight panel has a light-emitting driving circuit connected to each electrode of the organic electroluminescence element; and
the light-emitting driving circuit sequentially causes the light-emitting units of different colors constituting the organic electroluminescence element to emit light in accordance with selection of the shutter element by driving of the scan line.

7. The display device according to claim 1, wherein
the shutter element panel has color filters of different colors provided at each of the shutter elements; and
the organic electroluminescence element arranged in each of the partitioned areas is a white light-emitting element.

8. The display device according to claim 7, wherein
the shutter element panel has a plurality of scan lines and a plurality of signal lines extended in a direction different from that of the scan lines;
each of the shutter elements is arranged in a state connected to the scan line and the signal line at each of intersection portions between the scan line and the signal line;
the backlight panel has a light-emitting driving circuit connected to each electrode of the organic electroluminescence element; and
the light-emitting driving circuit causes the organic electroluminescence element to emit light in accordance with selection of the shutter element by driving of the scan line.
